(19) United States
(12) Patent Application Publication
(10) Pub. No.: US 2020/0006517 A1
(43) Pub. Date: Jan. 2, 2020

(54) SEMICONDUCTOR DEVICE AND METHOD FOR FABRICATING THE SAME

(71) Applicant: United Microelectronics Corp., Hsinchu (TW)

(72) Inventors: Yi-Fan Li, Tainan City (TW); Po-Ching Su, Tainan City (TW); Cheng-Chia Liu, Kaohsiung City (TW); Yen-Tsai Yi, Tainan City (TW); Wei-Chuan Tsai, Changhua County (TW); Chih-Chiang Wu, Taichung City (TW); Ti-Bin Chen, Tainan City (TW); Ching-Chu Tseng, Taichung City (TW)

(73) Assignee: United Microelectronics Corp., Hsinchu (TW)

(21) Appl. No.: 16/053,665

(22) Filed: Aug. 2, 2018

(30) Foreign Application Priority Data
Jul. 2, 2018 (CN) 201810706688.3

(51) Int. Cl. H01L 29/66; H01L 29/78; H01L 23/31

(52) U.S. Cl. CPC H01L 29/6656; H01L 29/6653; H01L 21/283; H01L 29/6659; H01L 23/3171; H01L 29/7833

(57) ABSTRACT

A structure of semiconductor device includes a gate structure, disposed on a substrate. A spacer is disposed on a sidewall of the gate structure, wherein the spacer is an l-like structure. A first doped region is disposed in the substrate at two sides of the gate structure. A second doped region is disposed in the substrate at the two sides of the gate structure, overlapping the first doped region. A silicide layer is disposed on the substrate within the second doped region, separating from the spacer by a distance. A dielectric layer covers over the second doped region and the gate structure with the spacer.

### CROSS-REFERENCE TO RELATED APPLICATION

This application claims the priority benefit of China application serial no. 201810706688.3, filed on Jul. 2, 2018. The entirety of the above-mentioned patent application is hereby incorporated by reference herein and made a part of this specification.

### BACKGROUND

### 1. Field of the Invention

The present invention generally relates to semiconductor fabrication technology, and particularly to the structure and fabrication method for the semiconductor device.

### 2. Description of Related Art

As the size of semiconductor device is greatly reduced, the transistor density is accordingly increasing. Thus, the gap between gates of transistors is also accordingly reduced. Based on the technology development for fabricating the gate structure, the gate as mentioned can also be involved in the fabrication process during the stage for forming the dummy gate. In an example, the dummy gate is removed to leave a space for subsequently forming a metal gate therein. In addition, further due to the development of the gate structure, the sidewall of the gate may have multiple layers of different spacers in accordance with different fabrication stages. In this situation, the gap between gates is further reduced.

Furthermore, after completion of the gate structure of transistor, as needed in the subsequent fabrication process in an example, it needs to form a contact etching stop layer (CESL) being conform to the gate structures and deposits an inter-layer dielectric (ILD) layer covering over the gate structure. Wherein, the CESL further reduce the gap between the gates of transistors. In this situation, before depositing the ILD layer, the gap between the gates of transistors has been rather small, easily resulting in the formation of a seam in the ILD layer between the gates of transistors. This would influence the performance of the semiconductor device.

If taking the way in reducing the thickness of the CESL for reducing the probability of forming seam, the mechanical strength provided by the CESL would be insufficient. Thus, the way of simply reducing the thickness of the CESL would cause another issue.

How to reduce the probability of forming seam between the gates is one of issues needed to be considered in the fabrication.

### SUMMARY OF THE INVENTION

In accordance with embodiments, the invention provides structure and fabrication method for the semiconductor device, at least being capable of reducing the probability of forming seam between the gates.

In an embodiment, the invention provides a structure of semiconductor device, comprising a gate structure, disposed on a substrate. A spacer is forming on a sidewall of the gate structure, wherein the spacer is an I-like structure. A first doped region is in the substrate at two sides of the gate structure. A second doped region is in the substrate at the two sides of the gate structure, overlapping with the first doped region. A silicide layer is disposed on the substrate within the second doped region, separating from the spacer by a distance. A dielectric layer is disposed over the second doped region and the gate structure with the spacer.

In an embodiment, as to the structure of semiconductor, the spacer on the gate structure is silicon nitride (SiN) or silicon carbonitride (SiCN).

In an embodiment, as to the structure of semiconductor, a plurality of the gate structures is disposed on the substrate.

In an embodiment, as to the structure of semiconductor, the gate structure comprises a gate insulation layer on the substrate and a gate layer, stacked from multiple layers, on the gate insulating layer.

In an embodiment, as to the structure of semiconductor, the first doped region in the substrate serves as a lightly doped drain region and the second doped region in the substrate serves as a source/drain region.

In an embodiment, as to the structure of semiconductor, the silicide layer is nickel silicide, cobalt silicide or titanium silicide, and wherein a silicon material of the silicide layer is provided from the substrate, separating from the spacer by a distance.

In an embodiment, as to the structure of semiconductor, the distance is set according to a width of a transient spacer disposed on the spacer of the gate structure while the transient spacer is removed.

In an embodiment, as to the structure of semiconductor, the dielectric layer is a contact etching stop layer (CESL), an inter-layer dielectric layer (ILD), or the CESL with the ILD.

In an embodiment, the invention provides a method for fabricating semiconductor device, comprising forming a gate structure on a substrate. Then, a first spacer is formed on a sidewall of the gate structure. A first doped region is formed in the substrate at two sides of the gate structure. A second spacer is formed on the first spacer and the substrate, wherein the second spacer comprises a liner spacer on the first spacer and an outer spacer on the liner spacer, wherein the liner spacer and the outer spacer are in different dielectric materials. A second doped region is formed in the substrate at the two sides of the gate structure. A silicide layer is formed on the substrate within the second doped region, abut the second spacer. The outer spacer and the liner spacer of the second spacer are removed. A dielectric layer is disposed over the second doped region and the gate structure with the first spacer.

In an embodiment, as to the method for fabricating semiconductor device, the first spacer is nitride, the liner spacer is silicon oxide and the outer spacer is silicon nitride.

In an embodiment, as to the method for fabricating semiconductor device, a plurality of the gate structures is formed on the substrate.

In an embodiment, as to the method for fabricating semiconductor device, the gate structure comprises a gate insulation layer on the substrate and a gate layer, stacked from multiple layers, on the gate insulating layer.

In an embodiment, as to the method for fabricating semiconductor device, the first doped region in the substrate serves as a lightly doped drain region and the second doped region in the substrate serves as a source/drain region.

In an embodiment, as to the method for fabricating semiconductor device, the silicide layer is nickel silicide, cobalt silicide or titanium silicide, and wherein a silicon material of the silicide layer is provided from the substrate abut the outer spacer of the second spacer.

In an embodiment, as to the method for fabricating semiconductor device, based on the etching selection to material, the outer spacer and the liner spacer are sequentially removed while the first spacer remains.

In an embodiment, as to the method for fabricating semiconductor device, the first spacer is formed by an I-like structure different from an L-like structure.

In an embodiment, as to the method for fabricating semiconductor device, the dielectric layer is a contact etching stop layer (CESL), an inter-layer dielectric layer (ILD), or the CESL with the ILD.

In an embodiment, as to the method for fabricating semiconductor device, the step for forming the second spacer comprises: forming a liner layer, covering over the substrate; forming an outer dielectric layer, covering the liner layer; and performing etching back process, removing the outer dielectric layer and the liner layer. The remaining portions of the outer dielectric layer and the liner layer forms the second spacer. The remaining portion of the liner layer is the liner spacer with an L-like structure. The remaining portion of the outer dielectric layer is the outer spacer, locating on a horizontal region of the L-like structure.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing, schematically illustrating a cross-sectional structure of a semiconductor device as looked into, according to an embodiment of the invention.

FIG. 2A to FIG. 2H are drawings, schematically illustrating cross-sectional structure of fabrication flow for the semiconductor device, according to an embodiment of the invention.

FIG. 3 is a drawing, schematically illustrating a cross-sectional structure of a semiconductor device with multiple gate structures, according to an embodiment of the invention.

FIG. 4 is a drawing, schematically illustrating a method for fabrication semiconductor device, according to an embodiment of the invention.

### DESCRIPTION OF THE EMBODIMENTS

The invention is directed to the fabrication technology of semiconductor device. In accordance with the requirement for increasing the integrated level for the integrated circuit, after technology development, the size of semiconductor device can be greatly reduced. Transistor is the essential element in the integrated circuit, its sizes is then also greatly reduced, in which the distance between adjacent transistors is accordingly reduced.

In the technology of fabricating semiconductor device, as the device size is greatly reduced, the space as to be filled with dielectric material would get small, accordingly. As a result, during the process to form the dielectric layer as needed by depositing some dielectric material to fill into the space, the seam in the dielectric layer would more easily occur.

Some embodiments are provided for describing the invention, but the invention is not just limited to the embodiments.

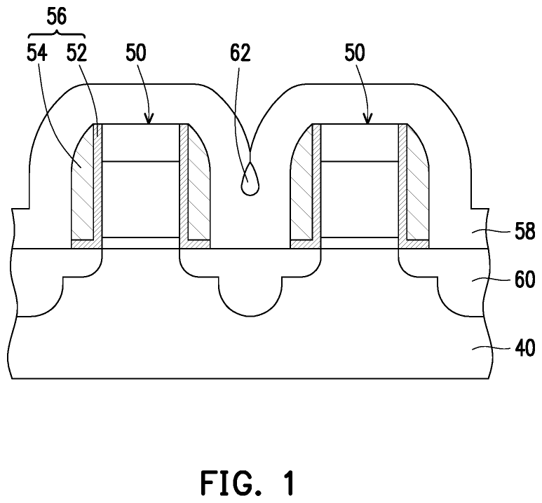

FIG. 1 is a drawing, schematically illustrating a cross-sectional structure of a semiconductor device as looked into, according to an embodiment of the invention. Referring to FIG. 1, in an embodiment, the invention has looked into the mechanism of occurring the seam in the semiconductor device while the device size is reduced for increasing the integrated level. Taking the gate structure of transistor as an example, a number of transistors are formed on a substrate 40, in which two adjacent transistors are taken as an example. The transistor includes a gate structure 50 formed on the substrate 40. The sidewall of the gate structure 50 has spacer 56 thereon. The spacer 56 in an example includes inner spacer 52 and an outer spacer 54. In the substrate 40, the doped region 60 located at two sides of the gate structure 50 serves as source region and the drain region.

A gap between adjacent two gate structures 50 would be reduced in accordance with the need for reducing the device size in all. The dielectric layer 58 is subsequently formed to cover over the gate structure 50. Thus, during the process for forming the dielectric layer 58 as subsequently needed through the depositing process, the seam 62 is easily occurring in the dielectric layer 58. The dielectric layer 58 in an example can be CESL or ILD layer, or both the CESL and the ILD layer.

The occurrence of seam 62 would influence the device performance and even cause failure of the whole transistor. The invention has observed the occurring mechanism of the seam 62, and proposed the technology to at least reduce the probability of occurring seam 62 after looking into the seam phenomenon.

In addition, as an embodiment, the dielectric layer 58 includes the CESL and the ILD layer as a stacked structure, the CESL is formed first at the bottom to maintain the tensile stress, the ILD layer is then subsequently deposited on the CESL. Thus, the CESL would further reduce the gap between the gate structures 50 and the seam 62 would more easily occur while depositing the ILD layer. If one way to reduce the thickness of the CESL is taken, it would be not able to provide the effect of sufficient tensile stress or etching stop capability. In this situation, the thickness of CESL needs to have the originally predetermined thickness. In either case that the thickness of CESL is over large, then seam 62 would even directly occur in the CESL.

In other words, after the invention has looked into the structure as shown in FIG. 1, and at least observed that the probability of occurring the seam 62 in the dielectric layer 58 is accordingly increasing when the gap between the gate structure 50 in a trend is reduced, in which the dielectric layer 58 can be a structure of single layer or multiple layers.

The invention has accordingly proposed the structure and the fabrication method for the semiconductor device, capable of at least reducing the probability of occurring seam 62 in the dielectric layer 58.

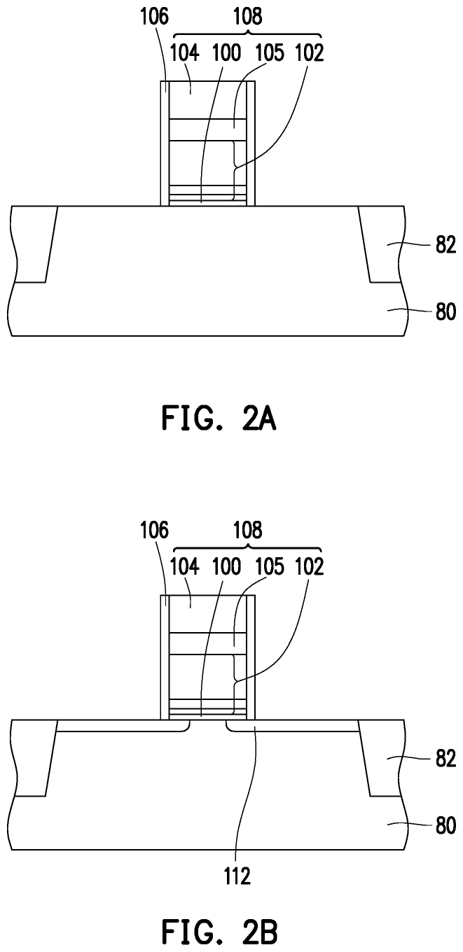

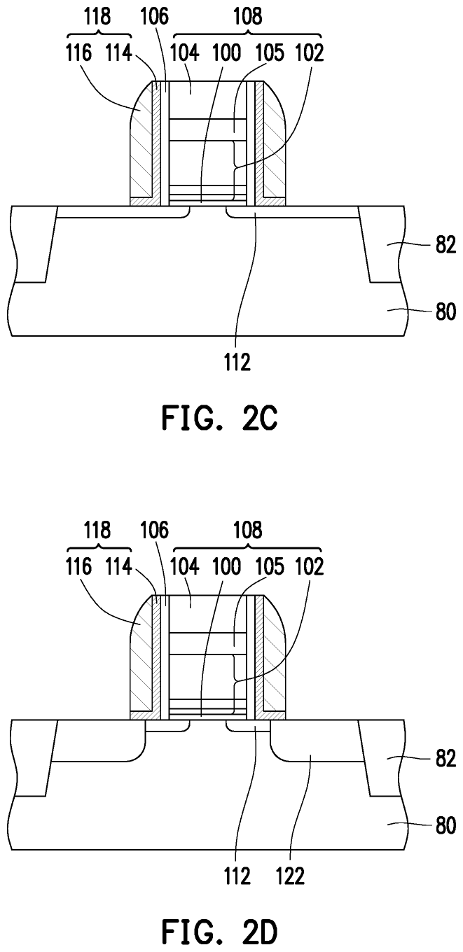

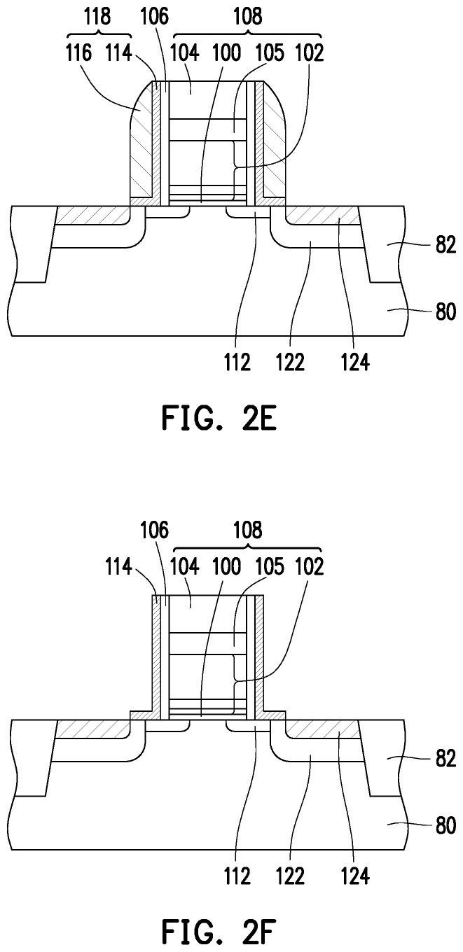

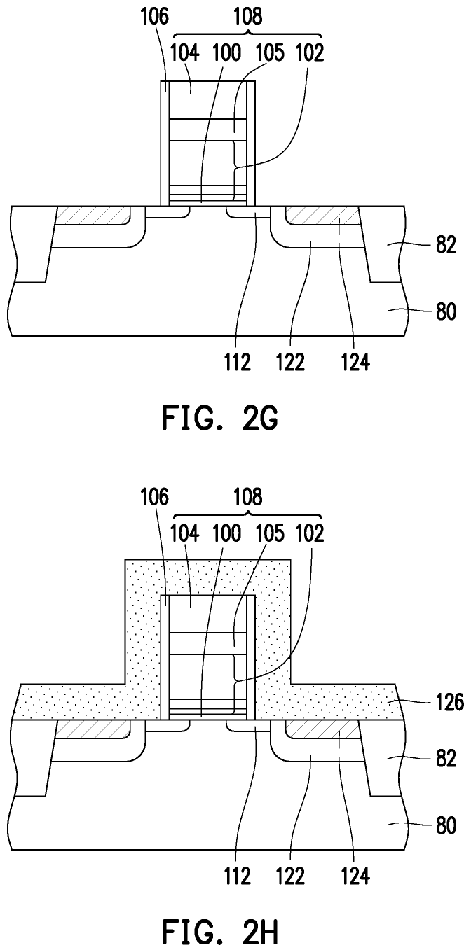

FIG. 2A to FIG. 2H are drawings, schematically illustrating cross-sectional structure of fabrication flow for the semiconductor device, according to an embodiment of the invention. Referring to FIG. 2A, it takes the fabrication flow for forming a single transistor as an example for descriptions. In the actual fabrication of semiconductor device, multiple transistors are involved and the transistors with the designed size are compactly formed together on the substrate 80. In an embodiment, the substrate 80 can be a silicon substrate. Alternatively, the substrate 80 may have a corresponding doped well with respect to the conductive type of transistor as actually needed. The doped well can also be defined by isolation structure 82 as an example. In the following descriptions, the substrate 80 represents a region for forming the transistor. The invention is not limited to a specific doping conductive type.

A gate structure 108 is formed on the substrate 80. The gate structure 108 is stacked from multiple material layers, including the gate insulating layer 100, the gate layer 102, and the cap layer 104. As actually needed, a nitride layer 105 can be further included between the gate layer 102 and the cap layer 104. The gate layer 102 as to the actual design can be a single layer or a structure stacked from multiple layers. The gate structure 108 in the invention as an embodiment of FIG. 2A is a structure stacked from multiple layers. However, the gate structure 108 in the invention is not limited to a specific internal structure.

The sidewall of the gate structure 108 is formed with a spacer 106. The structure of the spacer 106 is a perpendicular I-like structure, of which the bottom has no portion extending at the horizontal direction. Material of the spacer 106 can be silicon nitride (SiN) or silicon carbonitride (SiCN). The spacer 106 actually would remain at the end structure and can have a relatively smaller thickness.

Referring to FIG. 2B, an implanting process in an example is used to form a lightly doped region 112 at two sides of the gate structure 108. The lightly doped region 112 in an example serves as a lightly doped drain region (LDD).

Referring to FIG. 2C, based on design of a transistor structure, a spacer 118 with larger thickness is needed in fabrication process to be further formed on sidewalls of the gate structure 108. The spacer 118 is on the spacer 106. The spacer 118 is formed for some predetermined structures to be subsequently formed on the substrate 80 but not for actually serving as the spacer of the gate structure 108. In other words, the spacer 118 is to be removed in subsequent fabrication process. To be capable of removing the spacer 118 and keeping the spacer 106, the spacer 118 in an example includes a liner spacer 114 and an outer spacer 116. The liner spacer 114 and the spacer 106 are in different dielectric material. In an example for all, the spacer 106 is silicon nitride (SiN) or silicon carbonitride (SiCN), the liner spacer 114 is silicon oxide, the outer spacer 116 is silicon nitride.

In an example, formation of the spacer 118 can be done according to the way as usually known. A liner layer is formed for covering over the substrate 80. Further, an outer dielectric layer is formed for covering the liner layer. Then, an etching back process is performed for removing the outer dielectric layer and the liner layer. The remaining portions of the outer dielectric layer and the liner layer form the spacer 118. The remaining portion of the liner layer is the liner spacer 114 with an L-like structure, the remaining portion of the outer dielectric layer is the outer spacer 116, locating on a horizontal region of the L-like structure.

Referring to FIG. 2D, by the masking effect from the spacer 106 and the spacer 118, a doped region 122 is further formed in the substrate 80 at two sides of the gate structure 108 to serve as a source region and a drain region. As usually known, the doped region 122 overlaps and covers the lightly doped region 112.

Referring to FIG. 2E, the spacer 108 and the spacer 118 are also used to form a silicide layer 124 at the exposed surface of the substrate 80 at the doped region 122. Material of the silicide layer 124 in an example is nickel silicide, cobalt silicide or titanium silicide but not limited to. A silicon material of the silicide layer 124 is provided from the substrate 80. Due to the masking effect of the spacer 118, the silicide layer 124 and the spacer 106 are separating by a predetermined distance, which is depending on thickness of the spacer 118.

Referring to FIG. 2F, the spacer 118 as previously stated needs to be removed, so an etching process is used to firstly remove the outer spacer 116. Referring to FIG. 2G, subsequently, the liner spacer 114 can be removed by use of etchant with etching selectivity on the material, so spacer 106 is reserved. In an embodiment, the spacer 106 is nitride, the liner spacer 114 is oxide. As a result, the spacer 106 can be substantially reserved and the spacer 118 including the outer spacer 116 and the liner spacer 114 can be sequentially removed.

In an embodiment of the invention, the outer spacer 116 and the liner spacer 114 of the spacer 118 are removed, only the spacer 106 remains. Material of the spacer 106 is nitride, so the thickness can just be small and has already been sufficient to achieve a spacer with isolating effect on the gate structure 108. The spacer 106 is perpendicular as an I-structure different from the L-structure. The liner spacer 114 is the L-structure, of which the transverse portion is located on the substrate 80. The outer spacer 116 is disposed on the transverse portion of the liner spacer 114. The thickness of the spacer 118 would determine the distance between the silicide layer 124 and the spacer 106.

Referring to FIG. 2H, the other structures can be subsequently formed thereon, such as depositing dielectric layer 126. In an embodiment, the dielectric layer 126 can be CESL or ILD layer, or both.

As described in FIG. 2G, since the spacer 118 including the liner spacer 114 would be removed, then the distance between adjacent two gate structures can be widened, so the dielectric layer 126 can be more easily cover over the space between adjacent two gate structures and the probability of occurring seam is reduced.

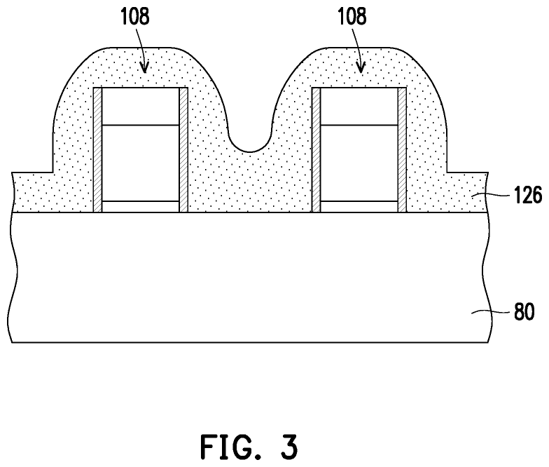

FIG. 3 is a drawing, schematically illustrating a cross-sectional structure of a semiconductor device with multiple gate structures, according to an embodiment of the invention. Referring to FIG. 3, multiple transistors are usually formed on the substrate 80. When the transistor size is reduced, the gap between the gate structures 108 is accordingly reduced. However, since the spacer on the gate structure 108 is thin structure, it can increase the space between the gate structures 108. When the dielectric layer 126 are subsequently depositing over the gate structures 108, it can be more easily to fill into the space between the gate structures 108, and then reducing the probability of occurring seam. The dielectric layer 126 as previously stated can be single layer or multiple layers without further descriptions here.

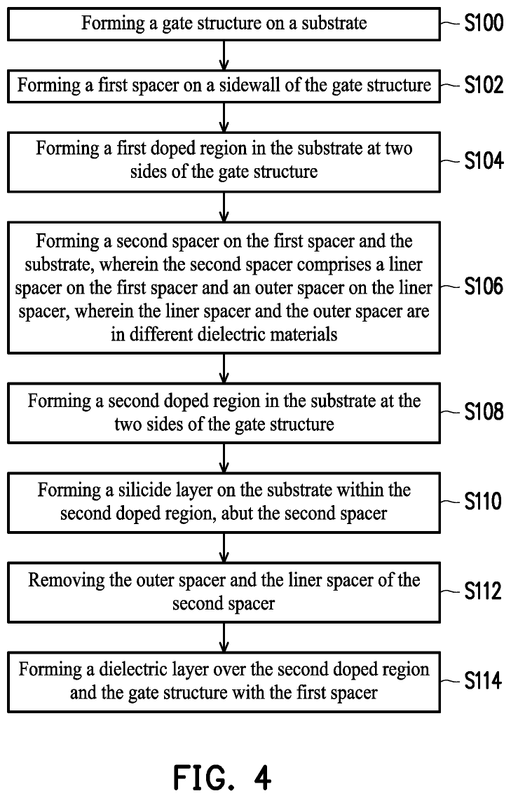

The invention can also be described as a method for fabricating semiconductor device. FIG. 4 is a drawing, schematically illustrating a method for fabrication semiconductor device, according to an embodiment of the invention.

Referring to FIG. 4 in accordance with FIGS. 2A-2H, the method for fabrication semiconductor device includes several steps. In step S100, a gate structure 108 is formed on a substrate 80. In step 102, a first spacer 106 is formed on a sidewall of the gate structure. In step S104, a first doped region 112 is formed in the substrate 80 at two sides of the gate structure 108. In step S106, a second spacer 118 is formed on the first spacer 106 and the substrate 80, wherein the second spacer 118 comprises a liner spacer 114 on the first spacer 106 and an outer spacer 116 on the liner spacer 114. The liner spacer 114 and the outer spacer 116 are in different dielectric materials. In step S108, a second doped region 122 is formed in the substrate 80 at the two sides of the gate structure 108. In step S110, a silicide layer 124 is formed on the substrate 80 within the second doped region 122, abut the second spacer 118. In step S112, the outer spacer 116 and the liner spacer 114 of the second spacer 118 are removed. In step S114, a dielectric layer 126 is disposed over the second doped region 122 and the gate structure 108 with the first spacer 106.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A structure of semiconductor device, comprising:
a first gate structure and a second gate structure, disposed on a substrate, wherein a gap is between the first gate structure and the second gate structure;
a spacer on a sidewall of the first gate structure and the second gate structure, wherein the spacer is an I-like structure in cross-section view from top to bottom of the gate structure on the substrate;
a first doped region in the substrate at two sides of the first gate structure and the second gate structure;
a second doped region in the substrate at the two sides of the first gate structure and the second gate structure, overlapping with the first doped region;
a silicide layer, disposed on the substrate within the second doped region, separating from the spacer by a distance, wherein a portion of the second doped region adjacent to the first doped region is not covered by the silicide layer; and
a dielectric layer, disposed over the second doped region and the gate structure with the spacer, wherein the portion of the second doped region directly contacts the dielectric layer,
wherein a part of the second doped region and a part of the silicide layer within the gap is a commonly shared by the first gate structure and the second gate structure,
wherein a part of the dielectric layer within the gap is directly contacting and between the spacer by the I-like structure of the first gate structure and the second gate structure.

2. The structure of semiconductor device of claim 1, wherein the spacer on the first gate structure and the second gate structure is silicon nitride (SiN) or silicon carbonitride (SiCN).

3. (canceled)

4. The structure of semiconductor device of claim 1, wherein each of the first gate structure and the second gate structure comprises:
a gate insulation layer on the substrate; and
a gate layer, stacked from multiple layers, on the gate insulating layer.

5. The structure of semiconductor device of claim 1, wherein the first doped region in the substrate serves as a lightly doped drain region and the second doped region in the substrate serves as a source/drain region.

6. The structure of semiconductor device of claim 1, wherein the silicide layer is nickel silicide, cobalt silicide or titanium silicide, and wherein a silicon material of the silicide layer is provided from the substrate, separating from the spacer by a distance.

7. The structure of semiconductor device of claim 6, wherein the distance is set according to a width of a transient spacer disposed on the spacer of the first gate structure and the second gate structure while the transient spacer is removed.

8. The structure of semiconductor device of claim 1, wherein the dielectric layer is a contact etching stop layer (CESL), an inter-layer dielectric layer (ILD), or the CESL with the ILD.

9. A method for fabricating semiconductor device, comprising:
forming a first gate structure and a second gate structure on a substrate, wherein a gap is between the first gate structure and the second gate structure;
forming a first spacer on a sidewall of the first gate structure and the second gate structure;
forming a first doped region in the substrate at two sides of the first gate structure and the second gate structure;
forming a second spacer on the first spacer and the substrate, wherein the second spacer comprises a liner spacer on the first spacer and an outer spacer on the liner spacer, wherein the liner spacer and the outer spacer are in different dielectric materials;
forming a second doped region in the substrate at the two sides of the first gate structure and the second gate structure;
forming a silicide layer on the substrate within the second doped region, abut the second spacer, wherein a portion of the second doped region under the second spacer is not covered by the silicide layer;
removing the outer spacer and the liner spacer of the second spacer; and
forming a dielectric layer over the second doped region and the first gate structure and the second gate structure with the first spacer, wherein the portion of the second doped region directly contacts the dielectric layer,
wherein a part of the second doped region and a part of the silicide layer within the gap is a commonly shared by the first gate structure and the second gate structure,
wherein a part of the dielectric layer within the gap is directly contacting and between the spacer by the I-like structure of the first gate structure and the second gate structure.

10. The method for fabricating semiconductor device of claim 9, wherein the first spacer is nitride, the liner spacer is silicon oxide and the outer spacer is silicon nitride.

11. (canceled)

12. The method for fabricating semiconductor device of claim 9, wherein each of the first gate structure and the second gate structure comprises:
a gate insulation layer on the substrate; and
a gate layer, stacked from multiple layers, on the gate insulating layer.

13. The method for fabricating semiconductor device of claim 9, wherein the first doped region in the substrate serves as a lightly doped drain region and the second doped region in the substrate serves as a source/drain region.

14. The method for fabricating semiconductor device of claim 9, wherein the silicide layer is nickel silicide, cobalt silicide or titanium silicide, and wherein a silicon material of the silicide layer is provided from the substrate abut the outer spacer of the second spacer.

15. The method for fabricating semiconductor device of claim 9, wherein based on the etching selection to material, the outer spacer and the liner spacer are sequentially removed while the first spacer remains.

16. The method for fabricating semiconductor device of claim 9, wherein the first spacer is formed by an I-like structure different from an L-like structure in cross-section view from top to bottom of the first gate structure and the second gate structure on the substrate.

17. The method for fabricating semiconductor device of claim 9, wherein the dielectric layer is a contact etching stop layer (CESL), an inter-layer dielectric layer (ILD), or the CESL with the ILD.

18. The method for fabricating semiconductor device of claim 9, wherein the step for forming the second spacer comprises:
forming a liner layer, covering over the substrate;
forming an outer dielectric layer, covering the liner layer; and
performing etching back process, removing the outer dielectric layer and the liner layer, wherein remaining portions of the outer dielectric layer and the liner layer form the second spacer,
wherein the remaining portion of the liner layer is the liner spacer with an L-like structure in cross-section view from top to bottom of the first gate structure and the second gate structure on the substrate, the remaining portion of the outer dielectric layer is the outer spacer, locating on a horizontal region of the L-like structure.
